(19) United States
(12) Patent Application Publication
(10) Pub. No.: US 2025/0285835 A1
(43) Pub. Date: Sep. 11, 2025

(54) Heated Dynamic Seal Rotary Union for Delivery of Cryogenic Fluid

(71) Applicant: Applied Materials, Inc., Santa Clara, CA (US)

(72) Inventors: Robert J. Mitchell, Winchester, MA (US); Guillermo Colom, Salisbury, MA (US); Jeffrey E. Krampert, Topsfield, MA (US)

(21) Appl. No.: 18/597,210

(22) Filed: Mar. 6, 2024

(51) Int. Cl. H01J 37/317; F16L 27/08; H01J 37/30

(52) U.S. Cl. CPC H01J 37/3171; F16L 27/0845; H01J 37/3002; H01J 2237/006

(57) ABSTRACT

A rotary union for use with a rotating platen that includes one or more lip seals is disclosed. The rotary union includes a rotary union shaft and a rotary union housing that surrounds the rotary union shaft. Heaters are disposed on the outer surfaces of the rotary union shaft and the rotary union housing. Additionally, a low thermal conductivity path is created between the center portion of the rotary union housing, where the lip seals are located, and the base of the rotary union housing, which contacts the cryogenic fluid. This low thermal conductivity path allows the lip seals to remain sufficiently warm so as to ensure good seal performance and reduced leakage.

### FIELD

Embodiments of the present disclosure relate to rotary unions for delivery of cryogenic fluids to a rotating platen, and more particularly, to rotary unions including a heated lip seal.

### BACKGROUND

In some workpiece processing systems, the workpiece is disposed on a platen, which can be rotated in multiple directions. This platen may also include electrical components, such as electrodes that are in communication with a power source. Additionally, this platen may be designed to heat or cool the workpiece. To achieve cooling, fluids travel toward the platen through fluid conduits. These fluid conduits are in communication with an external fluid source and an external fluid sink. Because the platen rotates, a rotary union is typically used to link the platen to the fluid source and sink.

The workpiece may be a semiconductor wafer, which is subjected to one or more processes while disposed on the platen. These processes may include etching, deposition and ion implantation.

In some particular embodiments, the platen is cooled to cold temperatures to enhance the process being performed on the workpiece. This may be achieved by passing a cold fluid through the fluid conduits in or near the platen. However, seals used in conventional rotary unions often fail to seal at cryogenic temperatures. For example, leakage may result from a shrinkage of the seal due to temperature changes, from the seal becoming brittle or less compliant due to the low temperatures.

Consequently, it would be beneficial if there was a rotary union that could withstand these extremely low temperatures without excessive leakage. Such a rotary union would make it possible to perform cryogenic processing of the workpiece using a rotating platen.

### SUMMARY

A rotary union for use with a rotating platen that includes one or more heated lip seals is disclosed. The rotary union includes a rotary union shaft and a rotary union housing that surrounds the rotary union shaft. Heaters are disposed on the outer surfaces of the rotary union shaft and the rotary union housing. Additionally, a low thermal conductivity path is created between the center portion of the rotary union housing, where the lip seals are located, and the base of the rotary union housing, which contacts the cryogenic fluid. This low thermal conductivity path allows the lip seals to remain sufficiently warm so as to ensure good seal performance and reduced leakage.

According to one embodiment, a rotary union for carrying a cryogenic fluid is disclosed. The rotary union comprises a rotary union shaft surrounding an internal fluid channel; a rotary union housing surrounding the rotary union shaft having a base in communication with a fluid inlet; a housing heater disposed on the rotary union housing; and one or more lip seals disposed between an outer surface of the rotary union shaft and an inner surface of a center portion of the rotary union housing; wherein the center portion of the rotary union housing is attached to the base of the rotary union housing by a connecting portion, and wherein the connecting portion comprises a tortuous pathway so as to increase a length of a path from the base to the center portion. In some embodiments, a shaft heater is disposed on an outer surface of the rotary union shaft. In some embodiments, the connecting portion of the rotary union housing comprises a low thermal conductivity pathway having a thermal resistance of 10° K/Watt or greater. In some embodiments, the rotary union housing comprises an outward facing portion, the center portion, the connecting portion and the base; and wherein the housing heater is disposed on the outward facing portion of the rotary union housing. In some embodiments, a thermal conductivity of a pathway from the housing heater to the center portion is at least 5 times greater than a thermal conductivity of the tortuous pathway. In some embodiments, channels are formed in the rotary union shaft, such that the outer surface of the rotary union shaft where the one or more lip seals are disposed is warmer than a temperature of the inner surface of the rotary union shaft which contacts the internal fluid channel. In certain embodiments, the outer surface of the rotary union shaft is at least 100° C. warmer than the temperature of the inner surface.

According to another embodiment, a rotary union for carrying a cryogenic fluid is disclosed. The rotary union comprises a rotary union shaft surrounding an internal fluid channel; a rotary union housing surrounding the rotary union shaft having a base in communication with a fluid inlet, the rotary union housing comprising an upper portion, a center portion, a connecting portion and a base; a housing heater disposed on an outer surface of the upper portion of the rotary union housing; and one or more lip seals disposed between the outer surface of the rotary union shaft and an inner surface of the center portion of the rotary union housing; wherein an inlet or an outlet for the cryogenic fluid is disposed in the base; and a ratio of a thermal conductivity of a path from the housing heater to the center portion of the rotary union housing to a thermal conductivity of a path from the base to the center portion of the rotary union housing is at least 5. In some embodiments, the ratio is at least 10. In some embodiments, the connecting portion of the rotary union housing comprises a tortuous pathway so as to increase a length of the path from the base to the center portion. In some embodiments, the outer surface of the rotary union shaft where the one or more lip seals are disposed is at least 100° C. warmer than a temperature of the base. In some embodiments, a shaft heater is disposed on an outer surface of the rotary union shaft. In some embodiments, channels are formed in the rotary union shaft, such that the outer surface of the rotary union shaft where the one or more lip seals are disposed is warmer than a temperature of the inner surface of the rotary union shaft which contacts the internal fluid channel.

According to another embodiment, a rotating platen assembly is disclosed. The rotating platen assembly comprises a platen base; a rotatable upper assembly rotatably coupled to the platen base about an axis of rotation, the rotatable upper assembly including a platen; and a first rotary union, comprising: a first rotary union shaft surrounding an internal fluid channel; a first rotary union housing surrounding the first rotary union shaft having a base in communication with a fluid inlet; a first housing heater disposed on the first rotary union housing; and one or more lip seals disposed between an outer surface of the first rotary union shaft and an inner surface of a center portion of the first rotary union housing; wherein the center portion of the first rotary union housing is attached to the base of the first rotary union housing by a connecting portion, and wherein the connecting portion comprises a tortuous pathway so as to increase a length of a path from the base to the center portion; wherein the first rotary union is disposed on a first side of the platen base such that the internal fluid channel is aligned with the axis of rotation, wherein the first rotary union is configured to receive cryogenic fluid through the fluid inlet and to deliver the cryogenic fluid to the platen or a thermal cooling plate disposed adjacent to the platen via a supply tube in communication with the internal fluid channel. In some embodiments, the rotating platen assembly comprises a second rotary union shaft surrounding an internal fluid channel; a second rotary union housing surrounding the second rotary union shaft having a base in communication with a fluid outlet; a second housing heater disposed on the second rotary union housing; and one or more lip seals disposed between an outer surface of the second rotary union shaft and an inner surface of a center portion of the second rotary union housing; wherein the center portion of the second rotary union housing is attached to the base of the second rotary union housing by a connecting portion, and wherein the connecting portion comprises a tortuous pathway so as to increase a length of a path from the base to the center portion; wherein the second rotary union is disposed on a second side of the platen base such that the internal fluid channel is aligned with the axis of rotation, wherein the second rotary union is configured to receive cryogenic fluid from the platen or the thermal cooling plate via a drain tube in communication with the internal fluid channel and to discharge the cryogenic fluid via the fluid outlet.

According to another embodiment, an ion implantation system is disclosed. The ion implantation system comprises a process chamber, housing the rotating platen assembly described above; an ion source to generate an ion beam; and one or more beamline components to direct the ion beam from the ion source to the process chamber. In some embodiments, a first shaft heater is disposed on an outer surface of the first rotary union shaft and a second shaft heater is disposed on an outer surface of the second rotary union shaft. In some embodiments, channels are formed in the first rotary union shaft, such that an outer surface of the first rotary union shaft where the one or more lip seals are disposed is warmer than a temperature of the inner surface of the first rotary union shaft. In some embodiments, a ratio of a thermal conductivity of a path from the first housing heater to the center portion of the first rotary union housing to a thermal conductivity of a path from the base to the center portion of the first rotary union housing is at least 5. In some embodiments, the ratio is at least 10.

### BRIEF DESCRIPTION OF THE FIGURES

For a better understanding of the present disclosure, reference is made to the accompanying drawings, which are incorporated herein by reference and in which:

FIG. 1 shows a ion implantation system that may utilize a cryogenic platen;

FIG. 2A shows a side view of the cryogenic platen;

FIG. 2B shows a rear view of the cryogenic platen;

FIG. 3 shows the cryogenic rotary union with heated lip seals used in the cryogenic platen according to one embodiment;

FIG. 4 shows an enlarged view of the rotary union and the components disposed therein; and

FIG. 5 shows the thermal profile of the components shown in FIG. 4.

### DETAILED DESCRIPTION

As described above, in certain systems, it is desirable to have a workpiece processed at very low temperatures, while disposed on a rotating platen. Further, mechanical seals are prone to leakage due to the low temperatures.

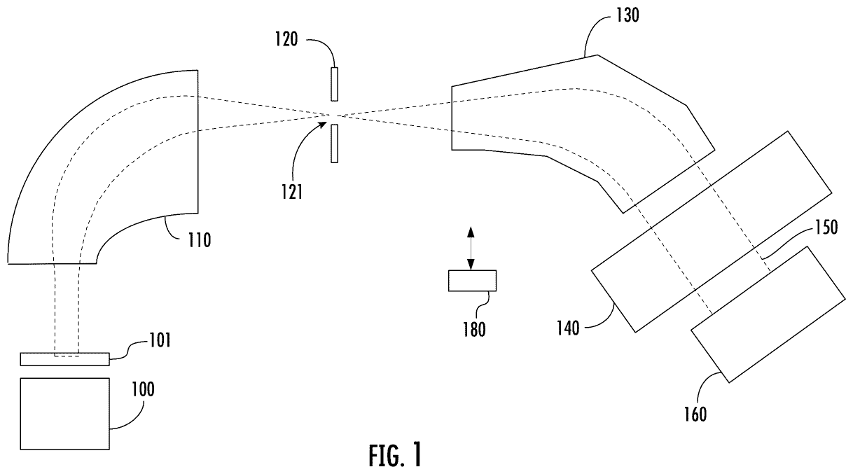

FIG. 1 shows an ion implantation system that may be used with a cryogenic platen. An ion source 100 is used to generate an ion beam 150. The ion source 100 may be a an indirectly heated cathode (IHC) ion source. Alternatively, the ion source 100 may be a capacitively coupled plasma source, an inductively coupled plasma source, a Bernas source or another source. Thus, the type of ion source is not limited by this disclosure. Disposed outside and proximate the extraction aperture of the ion source 100 is the extraction optics 101, which may comprise one or more electrodes.

Located downstream from the extraction optics 101 is a mass analyzer 110. The mass analyzer 110 uses magnetic fields to guide the path of the extracted ion beam. The magnetic fields affect the flight path of ions according to their mass and charge. A mass resolving device 120 that has a resolving aperture 121 is disposed at the output, or distal end, of the mass analyzer 110. By proper selection of the magnetic fields, only those ions in the ion beam 150 that have a selected mass and charge will be directed through the resolving aperture 121. Other ions will strike the mass resolving device 120 or a wall of the mass analyzer 110 and will not travel any further in the system.

A collimator 130 may be disposed downstream from the mass resolving device 120. The collimator 130 accepts the ions from the ion beam 150 that pass through the resolving aperture 121 and creates an ion beam formed of a plurality of parallel or nearly parallel beamlets. The output, or distal end, of the mass analyzer 110 and the input, or proximal end, of the collimator 130 may be a fixed distance apart. The mass resolving device 120 is disposed in the space between these two components.

Located downstream from the collimator 130 may be an acceleration/deceleration stage 140. The acceleration/deceleration stage 140 is a beam-line lens component configured to independently control deflection, deceleration, and focus of the ion beam. For example, the acceleration/deceleration stage 140 may be an electrostatic filter (EF). The ion beam 150 that exits the acceleration/deceleration stage 140 enters the process chamber 160.

Thus, one or more beamline components are disposed between the ion source 100 and the process chamber 160 to direct and guide the ion beam from the ion source 100 to the process chamber 160. These beamline components may include a mass analyzer, a mass resolving device, a collimator and/or an acceleration/deceleration stage.

A controller 180 may be in communication with one or more power supplies such that the voltage or current supplied by these power supplies may be monitored and/or modified. The controller 180 may include a processing unit, such as a microcontroller, a personal computer, a special purpose controller, or another suitable processing unit. The controller 180 may also include a non-transitory storage element, such as a semiconductor memory, a magnetic memory, or another suitable memory. This non-transitory storage element may contain instructions and other data that allows the controller 180 to perform the functions described herein.

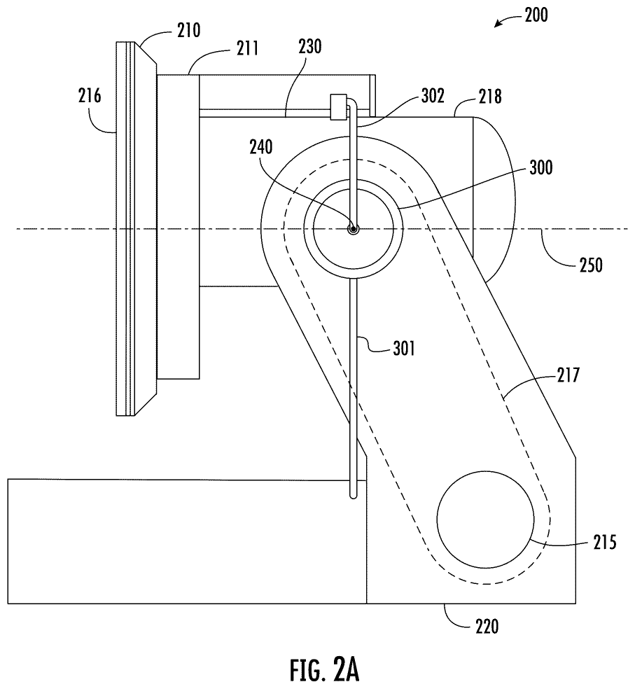

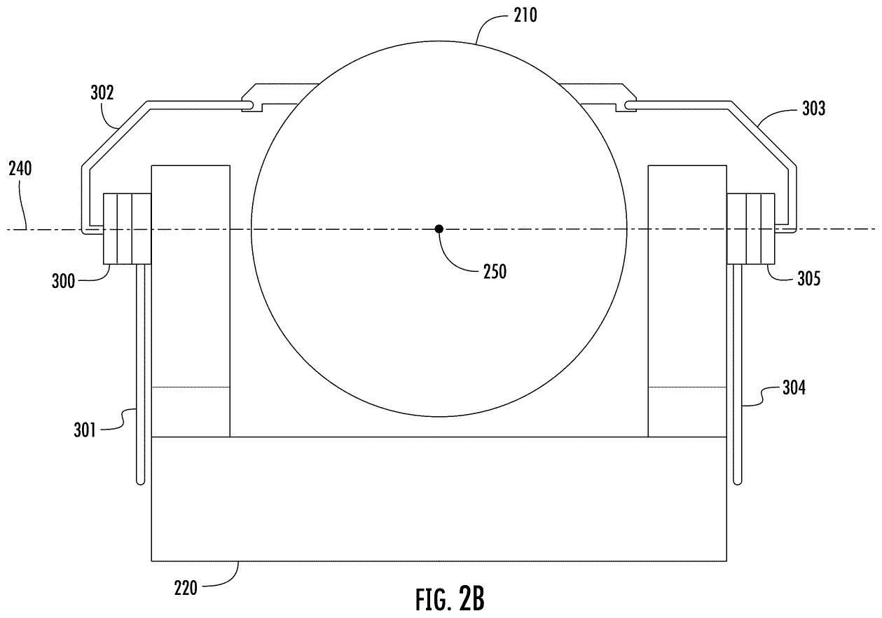

A rotating platen assembly 200 is disposed within the process chamber 160. FIG. 2A shows a side view of the rotating platen assembly 200, while FIG. 2B shows a rear view. The rotating platen assembly 200 includes a platen base 220. A rotatable upper assembly 230 is rotatably coupled to the platen base 220. A motor 215 is disposed in the platen base 220 and includes a drive belt 217 that allows rotation of the rotatable upper assembly 230 about axis 240.

Further, the rotatable upper assembly 230 includes a platen 210 to which the workpiece 216 is mounted. The rotatable upper assembly 230 may also include a housing 218 that contains other components. The platen 210 is rotatable about axis 250, which is orthogonal to the surface of the platen 210. In this figure, the rotatable upper assembly 230 also includes a thermal cooling plate 211 that is provided adjacent to the platen 210. The thermal cooling plate 211 does not rotate about axis 250. Rather, when the platen 210 rotates, the thermal cooling plate 211 may be linearly translated to create a small gap between the thermal cooling plate 211 and the platen 210 to reduce friction during rotation of the platen 210. When the platen 210 has completed its rotation, the thermal cooling plate 211 is linearly translated to contact the platen 210, allowing thermal conduction between the thermal cooling plate 211 and the platen 210. The thermal cooling plate 211 may include thermal channels through which cryogenic fluid can flow within the thermal cooling plate 211. The cryogenic fluid may be a gas or liquid. As cryogenic fluid flows through the thermal cooling plate 211, a workpiece 216 disposed on the platen 210 may be cooled to a desired temperature. The thermal channels in the thermal cooling plate 211 may connect to one or more supply tubes 302 and drain tubes 303, which, in turn, are each connected to a respective rotary union 300, 305. A rotary union 300 is connected to cryogenic fluid source through fluid inlet 301, while the second rotary union 305 is connected to a cryogenic fluid sink through a fluid outlet 304. In some embodiments, the cryogenic fluid may flow through a closed system, wherein the cryogenic fluid source and the cryogenic fluid sink are in communication with one another. For example, the cryogenic fluid source and cryogenic fluid sink may be a chiller, which receives the cryogenic fluid from fluid outlet 304, cools the fluid and recirculates it through fluid inlet 301. It will be appreciated that although thermal cooling plate 211 may be used, it is also contemplated that thermal cooling plate 211 may not be utilized. Thus, in some embodiments, the thermal channels may be integrated directly into the platen 210 such that the supply tubes 302 and the drain tubes 303 are in communication with the platen 210.

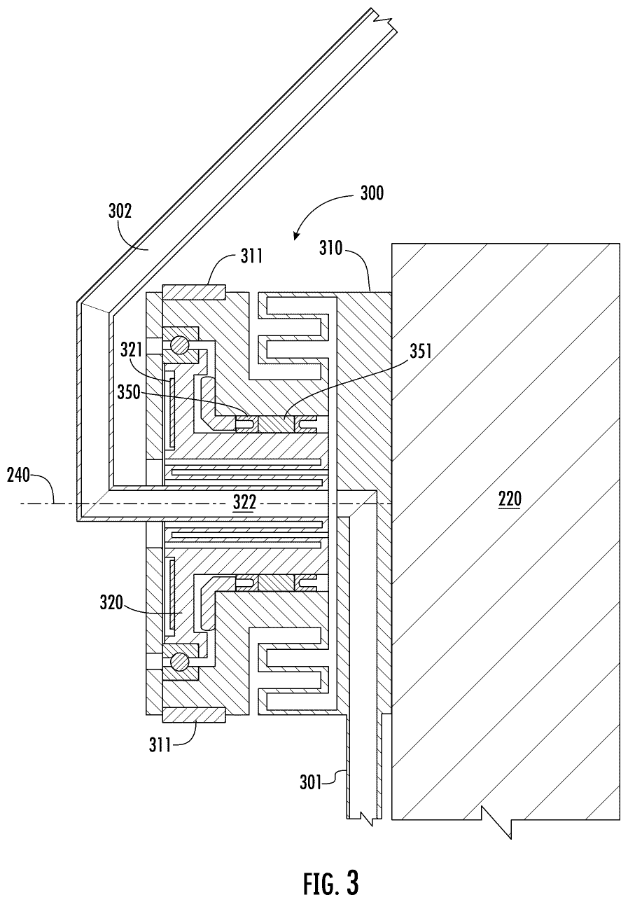

As shown in FIG. 3, one end of the rotary union 300 is affixed to the platen base 220. The rotary union 300 is in communication with a fluid inlet 301, which is fixed in position, and a supply tube 302, which rotates about axis 240. The rotary union 300 includes a rotary union housing 310, which is fixed in position and includes the connection for the fluid inlet 301. The rotary union 300 may include a rotary union shaft 320, which rotates and includes the connection for the supply tube 302. Further, the rotary union shaft 320 also includes an internal fluid channel 322, through which the cryogenic fluid passes.

The rotary union shaft 320 may be rotated using any suitable means. For example, the rotating shaft assembly may be moved by motor 215, such that movement of the rotatable upper assembly 230 causes rotation of the rotary union shaft 320.

A shaft heater 321 is mounted on the rotary union shaft 320. Electrical wires (not shown) are connected to the shaft heater 321.

A housing heater 311 is mounted on the rotary union housing 310.

Lastly, lip seals 350 are used to seal the gap between the rotary union housing 310 and the rotary union shaft 320. A seal spacer 351 may be disposed in the gap to maintain the separation between these components.

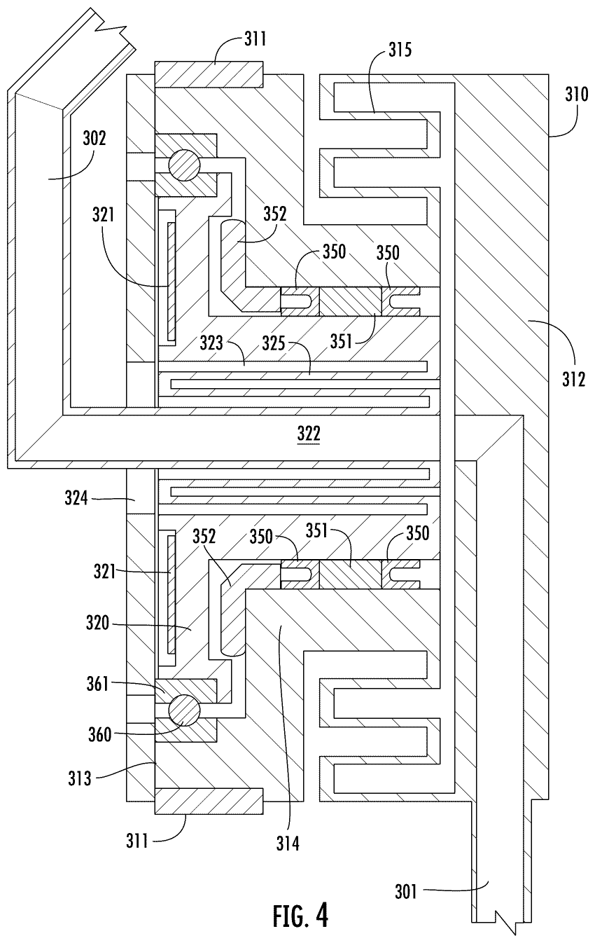

FIG. 4 shows an enlarged view of the rotary union 300 and the components disposed therein. The rotary union shaft 320 forms part of the outer wall of the internal fluid channel 322. Consequently, the inner surface of the rotary union shaft 320 is subjected to very low temperatures, such as less than −40° C. To generate the desired heat gradient between the inner surface of the rotary union shaft 320 and the outer surface of the rotary union shaft 320, one or more channels 323 are disposed in the rotary union shaft 320. One or more openings 324 are used to allow the one or more channels 323 to be in communication with the environment within the process chamber 160. Note that the one or more channels 323 are separated from one another by thin partitions 325. These thin partitions 325 serve to reduce heat transfer between the inner surface and the outer surface of the rotary union shaft 320. Thus, the rotary union shaft 320 may be configured as a hollow cylinder, wherein one or more channels 323 are disposed in the cylinder. The rotary union shaft 320 rotates with the rotatable upper assembly 230 and the supply tube 302.

The shaft heater 321 may be disposed on the outer surface of the rotary union shaft 320 near the exit of the internal fluid channel 322. This location may be selected as it is distant from the internal fluid channel 322 and the base 312 of the rotary union housing 310, which are at very low temperatures due to their contact with the cryogenic fluid.

The rotary union housing 310 comprises a base 312, which is affixed to the platen base 220 and is in communication with the fluid inlet 301 to allow the flow of cryogenic fluid. The rotary union housing 310 also comprises an outward facing portion 313. The outward facing portion 313 is that portion of the rotary union housing 310 that is closest to the exit of the internal fluid channel 322 and extends outward from the platen base 220. Outward facing portion 313 may be shaped as a hollow cylinder. The housing heater 311 is affixed to the outer surface of the outward facing portion 313 of the rotary union housing 310. Over at least a part of its length, the inner surface of the outward facing portion 313 may be concentric to the outer surface of the rotary union shaft 320. Further, bearings 360 are disposed between the inner surface of the outward facing portion 313 and the outer surface of the rotary union shaft 320. Bearing retaining flanges 361 may be disposed on either the inner surface of the outward facing portion 313 or the outer surface of the rotary union shaft 320 so as to retain the bearings 360 in position.

The outward facing portion 313 attaches to the center portion 314 of the rotary union housing 310. Like the outward facing portion, the center portion 314 may be shaped as a hollow cylinder. Over at least a part of its length, the inner surface of the center portion 314 may be concentric to the outer surface of the rotary union shaft 320. One or more lip seals 350 are disposed in the gap between the inner surface of the center portion 314 and the outer surface of the rotary union shaft 320. The seal spacer 351 is also located in the gap between the inner surface of the center portion 314 and the outer surface of the rotary union shaft 320 and serves to maintain the desired spacing between the lip seals 350. The seal spacer 351 may be PEEK (poly ether ether ketone) although other low friction plastics capable of operation at cryogenic temperatures may be used. Additionally, one or more seal retainers 352 may also be disposed in the gap between the inner surface of the center portion 314 and the outer surface of the rotary union shaft 320 to hold the lip seals 350 in position. Since the housing heater 311 is disposed on the outward facing portion 313 and the one or more lip seals 350 are located near the center portion 314, there is a high thermal conductivity path between the outward facing portion 313 and the center portion 314.

The center portion 314 of the rotary union housing 310 attaches to the base 312 through a connecting portion 315 which forms a low thermal conductivity path, resulting from a small cross sectional area and long distance from the base 312 to the seal area. As used herein, the term “low thermal conductivity path” refers to a path having a thermal resistance that is 10° K/Watt or greater. In some embodiments, the thermal resistance may be 15° K/Watt or greater. In some embodiments, the thermal resistance may be 20° K/Watt or greater. In other embodiments, the thermal resistance may be 30° K/Watt or greater. Specifically, the connecting portion 315 is a low thermal conductivity pathway between the base 312, which is at very cold temperatures, and the center portion 314, which is in contact with the one or more lip seals 350.

As is well known, the rate of heat transfer is directly proportional to the cross-section area of the pathway and inversely proportional to the length of that pathway. Thus, to achieve a low thermal conductivity pathway, the cross-sectional area of the connecting portion 315 may be reduced, as compared to the cross-sectional area of the center portion 314 and the outward facing portion 313. In some embodiments, the cross-sectional area of the connecting portion 315 may be one half or less than one half of the cross-sectional area of the center portion 314. In certain embodiments, the cross-sectional area of the connecting portion 315 may be ¼ of the cross-sectional area of the center portion 314 or less. Additionally, the length of the connecting portion 315 may be increased. This may be achieved by incorporating a tortuous pathway in the connecting portion 315. This tortuous pathway may comprise one or more folds, which serves to extend the path between the base 312 and the center portion 314. As shown in FIG. 4, in some embodiments, the connecting portion 315 may be a plurality of segments that extend in the axial direction, where the folds reverse the direction of the path. However, other embodiments are also possible. For example, the connecting portion 315 may have a plurality of segments that extend radially outward and inward, where the folds reverse the direction of the path. Further, the plurality of segments may extend diagonally, such that there is a radial and axial component. In certain embodiments, the thermal conductivity of the connecting portion 315 is at least 10 times less than the thermal conductivity of the outward facing portion 313 or the center portion 314. In some embodiments, the ratio of the thermal conductivity of the path from the outward facing portion 313 to the center portion 314 to the thermal conductivity of the path from the base 312 to the center portion 314 may be 5 or greater. In certain embodiments, the ratio may be 10 or greater. In some example embodiments, the ratio may be between 10 and 20. Further, while some of the figures show two folds, it is understood that additional folds may be introduced.

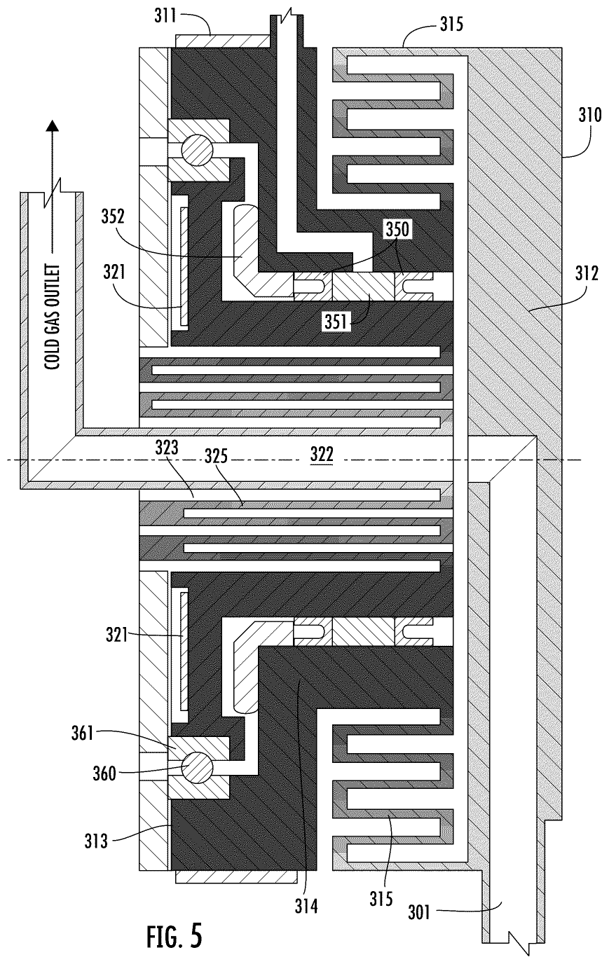

FIG. 5 shows the effects of the different thermal conductivities. In this figure, the shaft heater 321 and the housing heater 311 are both enabled and serve to heat the rotary union shaft 320 and the outward facing portion 313 of the rotary union housing 310, respectively. Additionally, cryogenic fluid is passing through the internal fluid channel 322, which serves to cool the base 312 and the inner surface of the rotary union shaft 320. The darkest shading is used to indicate the warmest components, while the lighter shading indicates colder components. The shading between these two extremes indicates an intermediate temperature.

Referring first to the rotary union shaft 320, the inner surface of that shaft is cold, due to its contact with the internal fluid channel 322 carrying cryogenic fluid. However, the channels 323 and thin partitions 325 create a low thermal conductivity pathway in the radial direction between the inner surface and the outer surface. Additionally, the shaft heater 321 is disposed on the outer surface of the rotary union shaft 320. Thus, a large thermal gradient is created in the radial direction in the rotary union shaft 320. In some embodiments, this thermal gradient may be greater than 100° C., such as between 110° and 150° C. However, note as well, that the distance from the shaft heater 321 in the axial or horizontal direction also affects the temperature of the rotary union shaft 320. Thus, the lower part of the rotary union shaft 320, which is spatially distant from the shaft heater 321, may be at a temperature that is between the temperature at the inner surface and the temperature of the shaft heater 321.

Turning next to the rotary union housing 310, the base 312 is cold, such as between −175° C. and −155° C., due to its contact with the cryogenic fluid. Meanwhile, the outward facing portion 313 of the rotary union housing 310 is relatively warm, such as greater than −25° C., due to the presence of the housing heater 311. The outward facing portion 313 and the center portion 314 have relatively thick cross-sectional areas, allowing high thermal conductivity between these two portions. Consequently, the housing heater 311 also serves to warm the center portion 314.

Therefore, the area of the rotary union housing 310 that contacts the one or more lip seals 350 is warmed by the housing heater 311, while the area of the rotary union shaft 320 that contacts the one or more lip seals 350 is warmed by shaft heater 321. Additionally, the low thermal conductivity pathway in the connecting portion 315 serves to reduce the flow of heat from the center portion 314 to the base 312, allowing the center portion 314 to remain at the desired temperature. Thus, the center portion 314 may be more than 100° C. warmer than the base 312.

The system described herein has many advantages. This system provides a superior technique for dynamically sealing a cryogenic fluid from the environment for use in a rotary union. By creating thermal isolation of a lip seal from the cryogenic fluid by means of a low thermal conductivity path between the cryogenic fluid and the lip seal, the seal temperature is maintained at a sufficiently high temperature such that good seal performance is achieved. This minimizes shrinkage of the lip seals due to thermal contraction, and allows the lip seals to maintain contact with the rotary union housing and the rotary union shaft. This also results in a longer life between servicing and a much lower leak rate to the environment compared to other dynamic seal technologies.

Note that FIGS. 3-5 show the rotary union that receives the cryogenic fluid through the fluid inlet 301 and delivers it to the platen 210. The second rotary union is configured in a same manner, but is the mirror image of that one shown in FIG. 3-5. In other words, if FIG. 3-5 show the rear view of the rotary union 300 in FIG. 2B, these would be front views of the second rotary union 305. Further, in second rotary union 305, the flow of cryogenic fluid is in the opposite direction. Cryogenic fluid flows into the internal fluid channel 322 from the drain tube 303 and exits through the fluid outlet 304 in the base 312 to a cryogenic fluid sink.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A rotary union for carrying a cryogenic fluid, comprising:
a rotary union shaft surrounding an internal fluid channel;
a rotary union housing surrounding the rotary union shaft having a base in communication with a fluid inlet;
a housing heater disposed on the rotary union housing; and
one or more lip seals disposed between an outer surface of the rotary union shaft and an inner surface of a center portion of the rotary union housing; wherein the center portion of the rotary union housing is attached to the base of the rotary union housing by a connecting portion, and wherein the connecting portion comprises a tortuous pathway so as to increase a length of a path from the base to the center portion.

2. The rotary union of claim 1, further comprising a shaft heater disposed on an outer surface of the rotary union shaft.

3. The rotary union of claim 1, wherein the connecting portion of the rotary union housing comprises a low thermal conductivity pathway having a thermal resistance of 10° K/Watt or greater.

4. The rotary union of claim 1, wherein the rotary union housing comprises an outward facing portion, the center portion, the connecting portion and the base; and wherein the housing heater is disposed on the outward facing portion of the rotary union housing.

5. The rotary union of claim 1, wherein a thermal conductivity of a pathway from the housing heater to the center portion is at least 5 times greater than a thermal conductivity of the tortuous pathway.

6. The rotary union of claim 1, wherein channels are formed in the rotary union shaft, such that the outer surface of the rotary union shaft where the one or more lip seals are disposed is warmer than a temperature of the inner surface of the rotary union shaft which contacts the internal fluid channel.

7. The rotary union of claim 6, wherein the outer surface of the rotary union shaft is at least 100° C. warmer than the temperature of the inner surface.

8. A rotary union for carrying a cryogenic fluid, comprising:
a rotary union shaft surrounding an internal fluid channel;
a rotary union housing surrounding the rotary union shaft having a base in communication with a fluid inlet, the rotary union housing comprising an upper portion, a center portion, a connecting portion and a base;
a housing heater disposed on an outer surface of the upper portion of the rotary union housing; and
one or more lip seals disposed between the outer surface of the rotary union shaft and an inner surface of the center portion of the rotary union housing;
wherein an inlet or an outlet for the cryogenic fluid is disposed in the base; and a ratio of a thermal conductivity of a path from the housing heater to the center portion of the rotary union housing to a thermal conductivity of a path from the base to the center portion of the rotary union housing is at least 5.

9. The rotary union of claim 8, wherein the ratio is at least 10.

10. The rotary union of claim 8, wherein the connecting portion of the rotary union housing comprises a tortuous pathway so as to increase a length of the path from the base to the center portion.

11. The rotary union of claim 10, wherein the outer surface of the rotary union shaft where the one or more lip seals are disposed is at least 100° C. warmer than a temperature of the base.

12. The rotary union of claim 8, further comprising a shaft heater disposed on an outer surface of the rotary union shaft.

13. The rotary union of claim 12, wherein channels are formed in the rotary union shaft, such that the outer surface of the rotary union shaft where the one or more lip seals are disposed is warmer than a temperature of the inner surface of the rotary union shaft.

14. A rotating platen assembly, comprising:
a platen base;
a rotatable upper assembly rotatably coupled to the platen base about an axis of rotation, the rotatable upper assembly including a platen; and
a first rotary union, comprising:
a first rotary union shaft surrounding an internal fluid channel;
a first rotary union housing surrounding the first rotary union shaft having a base in communication with a fluid inlet;
a first housing heater disposed on the first rotary union housing; and
one or more lip seals disposed between an outer surface of the first rotary union shaft and an inner surface of a center portion of the first rotary union housing; wherein the center portion of the first rotary union housing is attached to the base of the first rotary union housing by a connecting portion, and wherein the connecting portion comprises a tortuous pathway so as to increase a length of a path from the base to the center portion;
wherein the first rotary union is disposed on a first side of the platen base such that the internal fluid channel is aligned with the axis of rotation, wherein the first rotary union is configured to receive cryogenic fluid through the fluid inlet and to deliver the cryogenic fluid to the platen or a thermal cooling plate disposed adjacent to the platen via a supply tube in communication with the internal fluid channel.

15. The rotating platen assembly of claim 14, further comprising:
a second rotary union shaft surrounding an internal fluid channel;
a second rotary union housing surrounding the second rotary union shaft having a base in communication with a fluid outlet;
a second housing heater disposed on the second rotary union housing; and
one or more lip seals disposed between an outer surface of the second rotary union shaft and an inner surface of a center portion of the second rotary union housing; wherein the center portion of the second rotary union housing is attached to the base of the second rotary union housing by a connecting portion, and wherein the connecting portion comprises a tortuous pathway so as to increase a length of a path from the base to the center portion; wherein the second rotary union is disposed on a second side of the platen base such that the internal fluid channel is aligned with the axis of rotation, wherein the second rotary union is configured to receive cryogenic fluid from the platen or the thermal cooling plate via a drain tube in communication with the internal fluid channel and to discharge the cryogenic fluid via the fluid outlet.

16. An ion implantation system comprising:
a process chamber, housing the rotating platen assembly of claim 15;
an ion source to generate an ion beam; and
one or more beamline components to direct the ion beam from the ion source to the process chamber.

17. The ion implantation system of claim 16, further comprising a first shaft heater disposed on an outer surface of the first rotary union shaft and a second shaft heater disposed on an outer surface of the second rotary union shaft.

18. The ion implantation system of claim 16, wherein channels are formed in the first rotary union shaft, such that an outer surface of the first rotary union shaft where the one or more lip seals are disposed is warmer than a temperature of the inner surface of the first rotary union shaft.

19. The ion implantation system of claim 16, wherein a ratio of a thermal conductivity of a path from the first housing heater to the center portion of the first rotary union housing to a thermal conductivity of a path from the base to the center portion of the first rotary union housing is at least 5.

20. The ion implantation system of claim 19, wherein the ratio is at least 10.
